(19) United States
(12) Patent Application Publication
(10) Pub. No.: US 2013/0084707 A1
(43) Pub. Date: Apr. 4, 2013

(54) DRY CLEANING METHOD FOR RECOVERING ETCH PROCESS CONDITION

(71) Applicants: Mitsuru HASHIMOTO, Boise, ID (US); Akiteru KO, Schenectady, NY (US); Aline WULLUR, Boise, ID (US)

(72) Inventors: Mitsuru HASHIMOTO, Boise, ID (US); Akiteru KO, Schenectady, NY (US); Aline WULLUR, Boise, ID (US)

(73) Assignee: TOKYO ELECTRON LIMITED, Tokyo (JP)

(21) Appl. No.: 13/249,748

(22) Filed: Sep. 30, 2011

(51) Int. Cl. H01L 21/308

(52) U.S. Cl. 438/710; 257/E21.231

(57) ABSTRACT

A method of patterning a substrate is described. The method includes establishing a reference etch process condition for a plasma processing system. The method further includes transferring a mask pattern formed in a mask layer to one or more layers on a substrate using at least one plasma etching process in the plasma processing system to form a feature pattern in the one or more layers and, following the transferring, performing a multi-step dry cleaning process to substantially recover the reference etch condition. Furthermore, the multi-step dry cleaning process includes performing a first dry cleaning process step using plasma formed from a first dry clean process composition containing an oxygen-containing gas, and performing a second dry cleaning process step using plasma formed from a second dry clean process composition containing a halogen-containing gas.

### BACKGROUND OF THE INVENTION

1. Field of Invention

The invention relates to a method for dry cleaning a plasma processing system.

2. Description of Related Art

Dry plasma etching has become a critical step in the fabrication of microelectronic circuits on semiconductor substrates. And, as critical dimensions (CD) of these circuits become smaller, device yield becomes more sensitive to variations in the etching process as well as the occurrence of residue-induced defects on the substrate. Contributions to etching process variations and residue-induced defects may be minimized by controlling the accumulation of process by-products that condense or deposit on exposed surfaces in the plasma processing system.

Periodic dry cleaning of the plasma processing system, oftentimes using oxygen-containing plasma, is utilized to remove accumulated by-product deposition from the interior surfaces of the plasma processing system. In doing so, an acceptable etch process performance and substrate defect density may be maintained, thus, extending the operating time of the plasma processing system between system down-time for wet cleaning. However, due to the range of materials utilized in advanced semiconductor devices, the chemistry of etch process by-products is more complex and, thus, the ability to remove these by-products from the interior surfaces in the plasma processing system becomes more difficult.

### SUMMARY OF THE INVENTION

Embodiments of the invention relate to a method for dry cleaning a plasma processing system. Other embodiments of the invention relate to a method for dry cleaning a plasma processing system using multiple dry cleaning process steps.

According to one embodiment, a method of patterning a substrate is described. The method includes establishing a reference etch process condition for a plasma processing system. The method further includes transferring a mask pattern formed in a mask layer to one or more layers on a substrate using at least one plasma etching process in the plasma processing system to form a feature pattern in the one or more layers and, following the transferring, performing a multi-step dry cleaning process to substantially recover the reference etch condition. Furthermore, the multi-step dry cleaning process includes performing a first dry cleaning process step using plasma formed from a first dry clean process composition containing an oxygen-containing gas, and performing a second dry cleaning process step using plasma formed from a second dry clean process composition containing a halogen-containing gas.

### BRIEF DESCRIPTION OF THE DRAWINGS

In the accompanying drawings:

FIGS. 1 and 2 illustrate a method for patterning a substrate;

FIG. 3 provides a cross-sectional illustration of a plasma processing system for patterning a substrate;

FIG. 4 provides a flow chart illustrating a method for patterning a substrate according to an embodiment;

FIG. 5 shows a schematic representation of a plasma processing system according to an embodiment;

FIG. 6 shows a schematic representation of a plasma processing system according to another embodiment;

FIG. 7 shows a schematic representation of a plasma processing system according to another embodiment;

FIG. 8 shows a schematic representation of a plasma processing system according to another embodiment;

FIG. 9 shows a schematic representation of a plasma processing system according to another embodiment;

FIG. 10 shows a schematic representation of a plasma processing system according to another embodiment;

FIG. 11 shows a schematic representation of a plasma processing system according to another embodiment; and

FIG. 12 shows a schematic representation of a plasma processing system according to another embodiment.

### DETAILED DESCRIPTION OF SEVERAL EMBODIMENTS

In the following description, for purposes of explanation and not limitation, specific details are set forth, such as a particular geometry of a processing system, descriptions of various components and processes used therein. However, it should be understood that the invention may be practiced in other embodiments that depart from these specific details.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

“Substrate” as used herein generically refers to the object being processed in accordance with the invention. The substrate may include any material portion or structure of a device, particularly a semiconductor or other electronics device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or un-patterned, but rather, is contemplated to include any such layer or base structure, and any combination of layers and/or base structures. The description below may reference particular types of substrates, but this is for illustrative purposes only and not limitation.

As discussed above, contributions to etching process variations and residue-induced defects may be minimized by controlling the accumulation of etch process by-products that condense or deposit on (exposed) interior surfaces in the plasma processing system. However, the chemistry of etch process by-products is more complex, thus, making the removal of these etch process by-products more difficult. Consequently, etch process residue remains, which may adversely affect subsequent processing. As will be described in greater detail below, the inventors have observed that this etch process residue may cause a shift in an etch process condition for the etching process used to pattern a substrate.

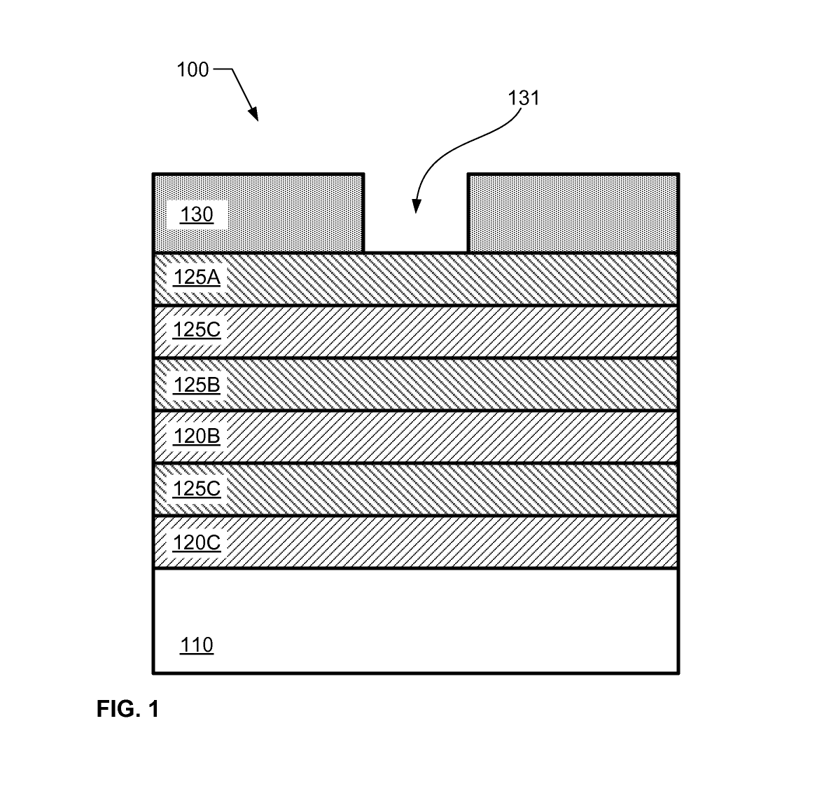

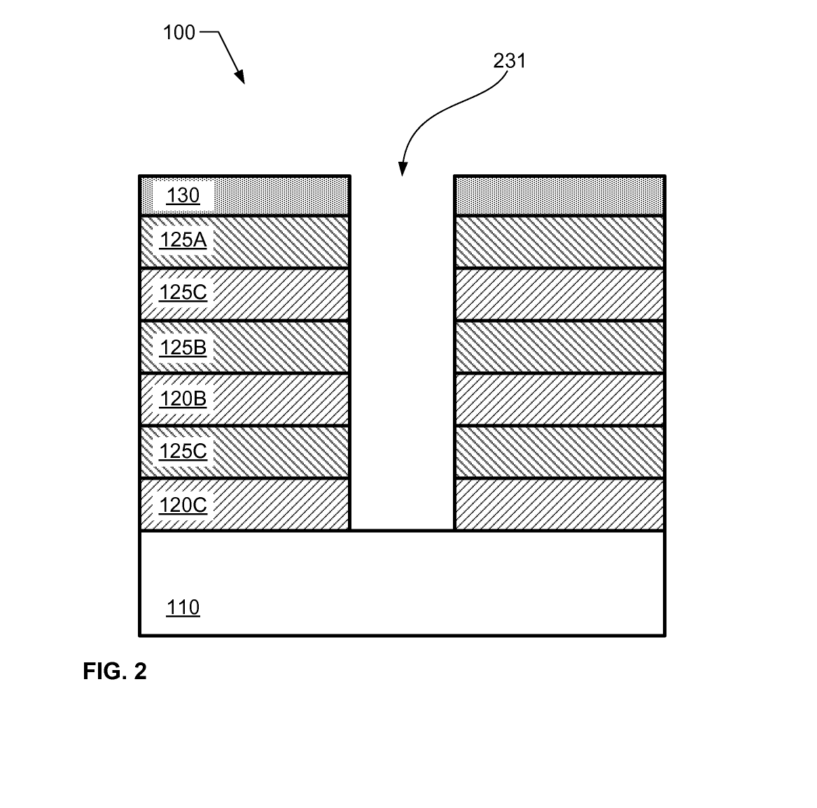

As an example, FIGS. 1 and 2 illustrate a method for patterning a substrate. Therein, a multi-layer film stack 100 is prepared on a substrate 110 having alternating layers of differing composition, wherein the alternating layers of differing composition include one or more layers of a first composition (125A, 125B, 125C) and one or more layers of a second composition (120A, 120B, 120C).

The one or more layers of a first composition (125A, 125B, 125C) may include a conductive material, a non-conductive material, or a semi-conductive material. As an example, the one or more layers of a first composition (125A, 125B, 125C) may include a silicon-containing material, or a metal-containing material. As another example, the one or more layers of a first composition (125A, 125B, 125C) may include Si and one or more elements selected from the group consisting of O, N, C, H, and Ge. As yet another example, the one or more layers of a first composition (125A, 125B, 125C) may include Si and O (e.g., SiO₂). The one or more layers of a first composition (125A, 125B, 125C) may include one or more sub-layers of differing material composition.

The one or more layers of a second composition (120A, 120B, 120C) may include a conductive material, a non-conductive material, or a semi-conductive material. As an example, the one or more layers of a second composition (120A, 120B, 120C) may include a silicon-containing material, or a metal-containing material. As another example, the one or more layers of a second composition (120A, 120B, 120C) may include Si and one or more elements selected from the group consisting of O, N, C, H, and Ge. As yet another example, the one or more layers of a second composition (120A, 120B, 120C) may include Si, such as polycrystalline silicon (poly-Si). The one or more layers of a second composition (120A, 120B, 120C) may include one or more sub-layers of differing material composition.

As shown in FIG. 1, a mask layer 130 is prepared on the multi-layer film stack 100 and a mask pattern 131 is formed in the mask layer 130 to expose a portion of the one or more layers of the first composition (125A, 125B, 125C). The mask layer 130 may comprise one or more layers, wherein the one or more layers includes a soft mask layer, a hard mask layer, a layer of radiation-sensitive material, a layer of photo-sensitive material, a layer of photo-resist (PR), an anti-reflective coating (ARC) layer, an organic dielectric layer (ODL), or an organic planarization layer (OPL), or any combination of two or more thereof.

Thereafter, as shown in FIG. 2, mask pattern 131 is transferred to the multi-layer film stack 100 using at least one plasma etching process to produce feature pattern 231. To etch the one or more layers of the first composition (125A, 125B, 125C) and the one or more layers of the second composition (120A, 120B, 120C), the at least one plasma etching process may include one or more etching process steps that includes one or more process gases containing as incipient ingredients atomic and/or molecular constituents capable of chemical reaction with both the layers of first composition and the layers of second composition.

For example, the at least one plasma etching process may include: (A) a single etching process step using plasma formed of one or more process gases containing as incipient ingredients atomic and/or molecular constituents capable of chemical reaction with both the layers of first composition and the layers of second composition; or (B) multiple etching process steps having a first etching process step using first plasma formed of one or more first process gases containing as incipient ingredients atomic and/or molecular constituents capable of chemical reaction with the layers of first composition, and a second etching process step using second plasma formed of one or more second process gases containing as incipient ingredients atomic and/or molecular constituents capable of chemical reaction with the layers of second composition.

When etching the one or more layers of a first composition (125A, 125B, 125C) that contain Si and O, the etching process may include plasma formed using a process gas having as an incipient ingredient a halogen-containing gas. Further yet, the etching process may include plasma formed using a process gas having as an incipient ingredient a fluorocarbon gas, or a fluorohydrocarbon gas, or both a fluorocarbon gas and a fluorohydrocarbon gas. The process gas may further include a noble gas. As an example, the etching process may include forming plasma using a process gas containing CF₄, C₄F₆, C₄F₈, C₅F₈, CH₂F₂, or CHF₃, or any combination of two or more thereof.

When etching the one or more layers of a second composition (120A, 120B, 120C) that contain Si, the etching process may include plasma formed using a process gas having as an incipient ingredient a halogen-containing gas. Further yet, the etching process may include plasma formed using a process gas having as an incipient ingredient a bromine-containing gas or a chlorine-containing gas. The process gas may further include a noble gas. As an example, the etching process may include forming plasma using a process gas containing HBr, Cl₂, NF₃, SF₆, or BCl₃, or any combination of two or more thereof.

When etching the one or more layers of a first composition (125A, 125B, 125C) that contain Si and O, and the one or more layers of a second composition (120A, 120B, 120C) that contain Si, the etching process may include plasma formed using a process gas containing CF₄, C₄F₆, C₄F₈, C₅F₈, CH₂F₂, CHF₃, HBr, Cl₂, NF₃, SF₆, or BCl₃, or any combination of two or more thereof. The process gas may further include a noble gas.

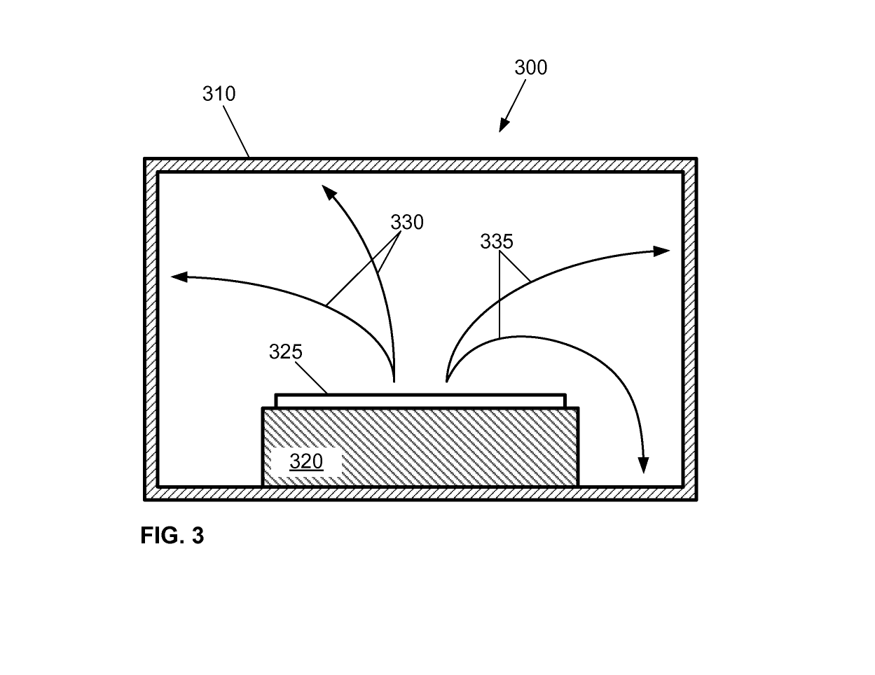

As illustrated in FIG. 3, the at least one plasma etching process may be performed in a plasma processing system 300 having a plasma processing chamber 310, and substrate holder 320, upon which a substrate 325 to be processed is affixed. During the etching of the one or more layers of a first composition (125A, 125B, 125C), first etch process by-products 330 may evolve from substrate 325, and condense or deposit on the interior surfaces of plasma processing chamber 310. Further, during the etching of the one or more layers of a second composition (120A, 120B, 120C), second etch process by-products 335 may evolve from substrate 325, and condense or deposit on the interior surfaces of plasma processing chamber 310.

To remove the first and second etch process by-products (330, 335) from the interior surfaces of the plasma processing system, a conventional dry cleaning process may be performed. However, as noted above and discussed in greater detail below, the inadequate removal of etch process residue, the first and second etch process by-products (330, 335), may cause a shift in an etch process condition from a reference etch process condition for the etching process used in the plasma processing system to pattern substrate 325.

TABLE 1

| | Process | Pressure | HF RF | LF RF | Flow Rates (sccm) | | | | | | | | |
|---|---|---|---|---|---|---|---|---|---|---|---|---|---|
| Process Condition | Step | (mTorr) | (W) | (W) | HBr | CHF₃ | CF₄ | Cl₂ | C₄F₈ | NF₃ | O₂ | Ar | He |
| Standard Dry Cleaning | Step 1 | 600 | 2150 | 0 | | | | | | 900 | | | |
| (DC) Process Condition | | | | | | | | | | | | | |
| Multi-Layer Etch | HM | 40 | 1000 | 600 | | 100 | 50 | | | | 20 | 100 | |
| Process Condition | ME | 50 | 1000 | 2500 | 225 | | | 50 | 30 | 55 | | | 300 |
| | OE | 20 | 1000 | 2500 | | | 10 | | | 40 | | | 300 |
| Etch Rate Check | Oxide | 90 | 700 | 1300 | 200 | | | | | 30 | 27 | | |
| Process Condition | Etch | | | | | | | | | | | | |
| Multi-Step Dry | Step 1 | 20 | 1000 | 2500 | | | | | | | 400 | | |
| Cleaning (DC) Process | Step 2 | 200 | 1750 | 0 | | | | | | 700 | 200 | | |
| Condition 1 | Step 3 | 50 | 1000 | 2500 | | | | | | | 800 | | |
| | Step 4 | 250 | 1750 | 0 | | | | | | | 800 | | |
| Multi-Step Dry | Step 1 | 20 | 1000 | 2500 | | | | | | | 400 | | |
| Cleaning (DC) Process | Step 2 | 200 | 1750 | 0 | | | | | | 700 | 200 | | |
| Condition 2 | Step 3 | 50 | 1000 | 2500 | | | | | | | 800 | | |
| | Step 4 | 250 | 1750 | 0 | | | | | | | 800 | | |

| | | | | BP | BP | | Etch |
|---|---|---|---|---|---|---|---|
| | Process | Gap | | CENTER | EDGE | Temperature | Time |
| Process Condition | Step | (mm) | RDC | (Torr) | (Torr) | (Deg. C.) | (sec) |
| Standard Dry Cleaning | Step 1 | | | 10 | 10 | 80/70/80 | 60 |
| (DC) Process Condition | | | | | | | |
| Multi-Layer Etch | HM | | | | | | 60 |
| Process Condition | ME | | | | | | 261 |
| | OE | | | | | | 30 |
| Etch Rate Check | Oxide | | 50/50 | 15 | 45 | 80/70/80 | 300 |
| Process Condition | Etch | | | | | | |
| Multi-Step Dry | Step 1 | | 50/50 | 15 | 15 | 80/80/80 | 60 |
| Cleaning (DC) Process | Step 2 | | 40/60 | 15 | 15 | 80/80/80 | 180 |
| Condition 1 | Step 3 | | 50/50 | 15 | 15 | 80/80/80 | 60 |
| | Step 4 | 35 | 40/60 | 15 | 15 | 80/80/80 | 60 |
| Multi-Step Dry | Step 1 | | 50/50 | 15 | 15 | 80/80/80 | 240 |
| Cleaning (DC) Process | Step 2 | | 40/60 | 15 | 15 | 80/80/80 | 720 |
| Condition 2 | Step 3 | | 50/50 | 15 | 15 | 80/80/80 | 240 |
| | Step 4 | 35 | 40/60 | 15 | 15 | 80/80/80 | 240 |

Table 1 provides exemplary process conditions for performing an etching process to transfer a pattern to a multi-layer film stack on a substrate. The multi-layer film stack includes alternating layers of SiO₂ (or, more generally, SiOₓ) and silicon, such as poly-crystalline Si (poly-Si), arranged similar to the multi-layer film stack 100 depicted in FIGS. 1 and 2.

The multi-layer etch process condition comprises three process steps including a hard mask open etch process step (“HM”) wherein the pattern is transferred to a hard mask layer (e.g., silicon nitride, SiₓN_{y}), a main etch process step (“ME”) wherein the pattern is transferred to the multi-layer film stack, and an over-etch process step (“OE”) wherein the pattern transfer is completed for the entire substrate. The process composition for the three etch process steps is as follows: (A) CF₄, CHF₃, O₂, Ar; (B) HBr, Cl₂, C₄F₈, NF₃, He; (C) CF₄, NF₃, He. However, other process compositions and/or etch process conditions are possible. The values for each process parameter are exemplary and may vary.

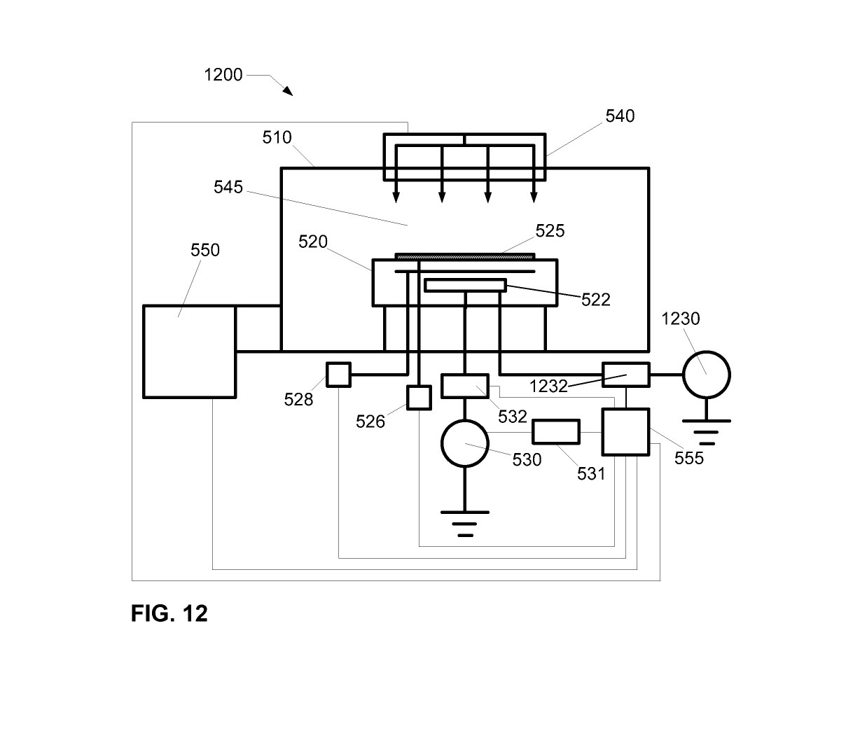

For the hard mask open etch process step, the main etch process step, and the over-etch process step, a process condition is recited including a gas pressure (millitorr, mTorr) in the plasma processing chamber, a high frequency (HF; e.g., 100 MHz) lower electrode (LEL) radio frequency (RF) power (watts, W), a low frequency (LF; e.g., 3 MHz) LEL RF power (watts, W), an HBr flow rate (standard cubic centimeters per minute, sccm), a CHF₃ flow rate, a CF₄ flow rate, a Cl₂ flow rate, a C₄F₈ flow rate, an NF₃ flow rate, an O₂ flow rate, an Ar flow rate, a He flow rate, a gap spacing (millimeters, m) (e.g., spacing between upper electrode (UEL) and LEL), an RDC value, a temperature set for components in the plasma processing chamber (° C., deg. C.) (Temperatures are as follows: UEL temperature/Wall temperature/LEL temperature), and a process (or etch) time (seconds, sec). The plasma processing system may include plasma processing system (1200) depicted in FIG. 12.

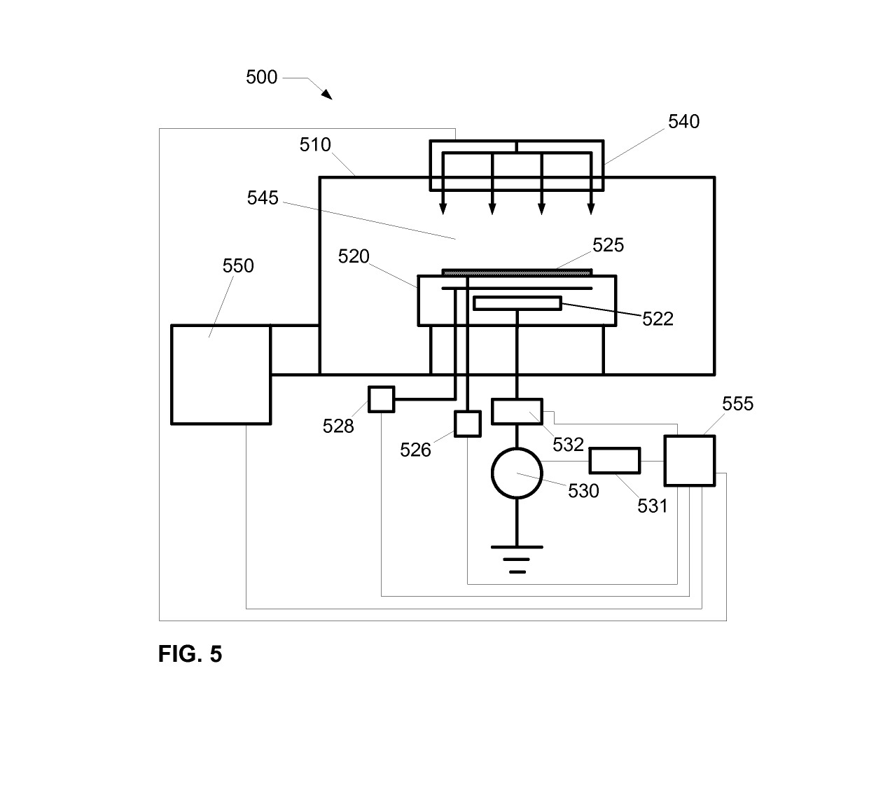

In alternate embodiments, RF power may be supplied to the upper electrode and not the lower electrode. In other alternate embodiments, RF power may be supplied to both the lower electrode and the upper electrode. In yet other alternate embodiments, RF power and/or DC power may be coupled in any of the manners described through FIGS. 5 to 12.

The time duration to perform a specific etching process step or dry cleaning process step may be determined using design of experiment (DOE) techniques or prior experience; however, it may also be determined using endpoint detection. One possible method of endpoint detection is to monitor a portion of the emitted light spectrum from the plasma region that indicates when a change in plasma chemistry occurs due to change or substantially near completion of the removal of a particular material layer from the substrate and contact with the underlying thin film. After emission levels corresponding to the monitored wavelengths cross a specified threshold (e.g., drop to substantially zero, drop below a particular level, or increase above a particular level), an endpoint can be considered to be reached. Various wavelengths, specific to the etch chemistry being used and the material layer being etched, may be used. Furthermore, the etch time can be extended to include a period of over-etch, wherein the over-etch period constitutes a fraction (i.e., 1 to 100%) of the time between initiation of the etch process and the time associated with endpoint detection.

The RDC value refers to a gas flow distribution parameter for the upper electrode (RDC). In some embodiments, the upper electrode may include a center gas distribution zone and an edge gas distribution zone. The value of the “RDC” parameter indicates the relative amount of gas flow distributed to the center and edge gas distribution zones. When RDC=50/50, the gas flow coupled to the edge gas distribution zone is equal to the gas flow coupled to the center gas distribution zone.

Furthermore, Table 1 provides exemplary process conditions for performing a standard dry cleaning (DC) process to remove etch process residue formed on interior surfaces of the plasma processing system and reset the etch process condition for the plasma processing system. The standard DC process condition uses a process composition containing NF₃.

Further yet, Table 1 provides exemplary process conditions for performing an etch rate check process on a blanket oxide (SiO₂) substrate to establish a reference etch process condition and, thereafter, assess the cleanliness of the plasma processing system. The etch rate check process condition uses a process composition containing HBr, NF₃, and He.

Now, turning to Table 2, the results for an etch rate check sequence are provided. The etch rate check sequence began with a reference etch rate check that included: (A) performing the standard DC process condition in Table 1 with a silicon substrate for 60 sec; and (B) performing the etch rate check process condition in Table 1 on a blanket oxide (SiO₂) substrate for 300 sec. The reference etch process condition was established at an etch rate of 40.5 nm/min (nanometers per minute).

TABLE 2

| | | | | Etch |
|---|---|---|---|---|
| | | Sub- | Dura- | Rate |
| | | strate | tion | (nm/ |
| Etch Rate Check Sequence | Process Condition | Type | (sec) | min) |
| Reference Etch Rate Check | Standard DC | Silicon | 60 | 40.5 |
| | Etch Rate Check | Oxide | 300 | |
| Season Plasma Processing | Standard DC | Silicon | 60 | |
| system with Multi-Layer | Multi-Layer Etch | Oxide | 360 | |
| Etch Process Condition | | | | |
| Etch Rate Check | Standard DC | Silicon | 60 | 46.2 |
| | Etch Rate Check | Oxide | 300 | |
| Season Plasma Processing | Standard DC | Silicon | 60 | |
| system with Multi-Layer | Multi-Layer Etch | Oxide | 360 | |
| Etch Process Condition | Standard DC | Silicon | 60 | |
| | Multi-Layer Etch | PR | 360 | |
| Etch Rate Check | Standard DC | Silicon | 60 | 46.2 |
| | Standard DC | Silicon | 60 | |
| | Etch Rate Check | Oxide | 300 | |
| | Standard DC | Silicon | 60 | |
| Multi-Step Dry Cleaning | Multi-Step DC 1 | Silicon | 360 | 40.5 |
| (DC) Process Condition | Etch Rate Check | Oxide | 300 | |
| 1 & Etch Rate Check | | | | |
| Multi-Step Dry Cleaning | Multi-Step DC 1 | Silicon | 360 | 40.7 |
| (DC) Process Condition | Multi-Step DC 2 | Silicon | 7200 | |
| 2 & Etch Rate Check | Etch Rate Check | Oxide | 300 | |

Upon establishing the reference etch process condition, the plasma processing system was seasoned using the multi-layer etch process with a blanket oxide substrate. The seasoning of the plasma processing system included: (a) resetting the plasma processing system using the standard DC process condition in Table 1 with a silicon substrate for 60 sec; and (b) performing the multi-layer etch process condition in Table 1 on an oxide substrate for 360 sec. Then, an etch rate check was performed that included: (i) performing the standard DC process condition in Table 1 with a silicon substrate for 60 sec; and (ii) performing the etch rate check process condition in Table 1 on a blanket oxide (SiO₂) substrate for 300 sec. As presented in Table 2, the etch process condition drifted from the reference etch process condition to an etch rate of 46.2 nm/min (nanometers per minute).

Thereafter, the plasma processing system was seasoned again using the multi-layer etch process with a blanket photo-resist (PR) substrate. The re-seasoning of the plasma processing system included: (a) resetting the plasma processing system using the standard DC process condition in Table 1 with a silicon substrate for 60 sec; (b) performing the multi-layer etch process condition in Table 1 on an oxide substrate for 360 sec; (c) resetting the plasma processing system using the standard DC process condition in Table 1 with a silicon substrate for 60 sec; and (d) performing the multi-layer etch process condition in Table 1 on a PR substrate for 360 sec. Then, again, an etch rate check was performed that included: (i) performing the standard DC process condition in Table 1 with a silicon substrate for 60 sec; (ii) performing the standard DC process condition in Table 1 again with a silicon substrate for 60 sec; (iii) performing the etch rate check process condition in Table 1 on a blanket oxide (SiO₂) substrate for 300 sec; and (iv) performing the standard DC process condition in Table 1 yet again with a silicon substrate for 60 sec to reset the plasma processing system. As presented in Table 2, the etch process condition remained the same at an etch rate of 46.2 nm/min (nanometers per minute).

The inventors surmise that the drift in the etch rate process condition from the reference etch rate process condition was due to the formation of different types of etch process residue, i.e., at least the first and second etch by-products noted above in FIG. 3. For example, using the multi-layer etch process condition, the inventors suspect that carbon-containing etch process residue, such as CFₓ, and bromine-containing etch process residue, such as SIBrₓO_{y}, may be present on interior surfaces of the plasma processing system. And, accordingly, the standard DC process condition is inadequate for removing these different types of etch process residue.

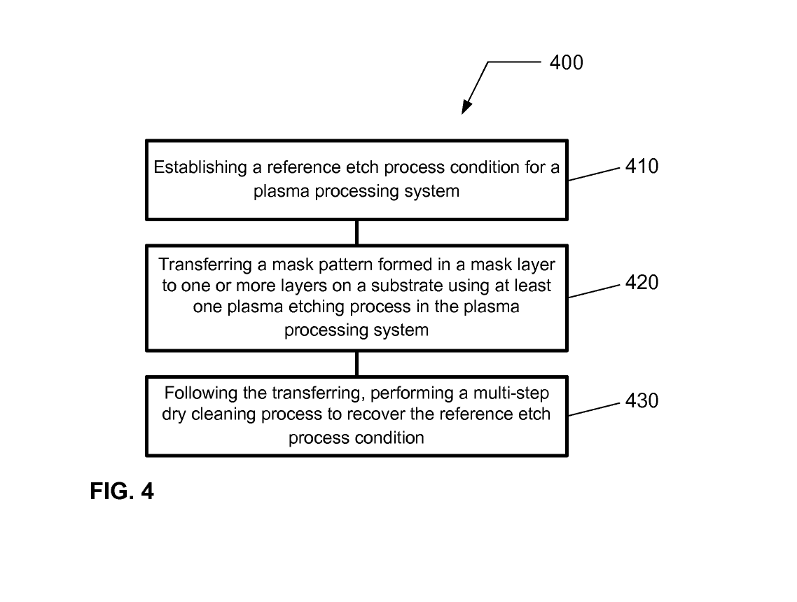

Therefore, according to an embodiment, a method for patterning a substrate is illustrated in FIG. 4. As shown in FIG. 4, the method comprises a flow chart 400 beginning in 410 with establishing a reference etch process condition for a plasma processing system. The plasma processing system may include any one of the plasma processing systems illustrated in FIGS. 5 through 12 and described below. For example, the plasma processing system may include plasma processing system (1200) depicted in FIG. 12.

The substrate may include a bulk silicon substrate, a single crystal silicon (doped or un-doped) substrate, a semiconductor-on-insulator (SOI) substrate, or any other semiconductor substrate containing, for example, Si, SiC, SiGe, SiGeC, Ge, GaAs, InAs, InP, as well as other III/V or II/VI compound semiconductors, or any combination thereof. The substrate can be of any size, for example a 200 mm (millimeter) substrate, a 300 mm substrate, or an even larger substrate. As noted above, the substrate may include one or more patterned and/or un-patterned layers and/or structures formed thereon.

For example, the substrate may include a multi-layer film stack (100; see FIGS. 1 and 2) formed thereon having alternating layers of differing composition, wherein the alternating layers of differing composition include one or more layers of a first composition (125A, 125B, 125C; see FIGS. 1 and 2) and one or more layers of a second composition (120A, 120B, 120C; see FIGS. 1 and 2). As described above, the one or more layers of a first composition (125A, 125B, 125C) may include Si and one or more elements selected from the group consisting of O, N, C, and H (e.g., SiO₂), and the one or more layers of a second composition (120A, 120B, 120C) may include Si (e.g., poly-crystalline silicon).

The reference etch process condition may include an etch rate of at least one of the layers of differing material composition, an etch selectivity between two or more of the layers of differing material composition, a critical dimension (CD) for a feature pattern formed in at least one of the layers of differing material composition, or a CD bias for the feature pattern, or any combination of two or more thereof. Furthermore, the reference etch process condition may include an etch uniformity of the etch rate, the etch selectivity, the critical dimension, or the CD bias, or a combination of two or more thereof. Further yet, the reference etch process condition may include an etch rate of a reference material on a reference substrate.

In one embodiment, the reference etch process condition is established by performing an etch rate check process on a substrate, such as a blanket oxide (SiO₂) substrate. For example, the etch rate check process may include the etch rate check process condition provided in Table 1.

In 420, a mask pattern formed in a mask layer is transferred to one or more layers on the substrate using at least one plasma etching process in the plasma processing system to form the feature pattern in the one or more layers. The at least one plasma etching process used in the plasma processing system may include any one of the etching processes described above, such as the multi-layer etch process condition provided in Table 1.

In 430, following the transferring, a multi-step dry cleaning process is performed to substantially recover the reference etch process condition. The multi-step dry cleaning process may include: performing a first dry cleaning process step using plasma formed from a first dry clean process composition containing an oxygen-containing gas, and performing a second dry cleaning process step using plasma formed from a second dry clean process composition containing a halogen-containing gas.

The first dry clean process composition contains oxygen (O). For example, the first dry clean process composition may contain O, O₂, O₃, CO, CO₂, NO, N₂O, or NO₂, or any combination of two or more thereof.

The first dry cleaning process step includes: setting a pressure in the plasma processing system; setting one or more flow rates for the first dry clean process composition; and setting a first radio frequency (RF) power level for a first RF signal applied to a substrate holder upon which the substrate rests, wherein the first RF signal has a RF frequency less than or equal to 10 MHz (i.e., the first RF signal may be a low frequency (LF) RF signal). The first dry cleaning process step may further include setting a second radio frequency (RF) power level for a second RF signal applied to the plasma processing system, wherein the second RF signal has a RF frequency greater than 10 MHz (i.e., the second RF signal may be a high frequency (HF) RF signal). Additionally, the second RF signal may be applied to the substrate holder along with the first RF signal.

In one embodiment, the first dry cleaning process step may comprise a process parameter space that includes: a chamber pressure ranging up to about 1000 mTorr (millitorr) (e.g., up to about 200 mTorr, or up to about 100 mTorr, or about 10 to 60 mTorr), a process gas flow rate ranging up to about 2000 sccm (standard cubic centimeters per minute) (e.g., up to about 1000 sccm), a second RF power level coupled to the lower electrode (LEL) (e.g., electrode 522 in FIG. 12) ranging up to about 2000 W (watts), and a first RF power level coupled to the LEL (e.g., electrode 522 in FIG. 12) ranging up to about 3000 W. Also, the RF frequency for the first RF signal can range from about 0.1 MHz to about 10 MHz, e.g., about 3 MHz. In addition, the RF frequency for the second RF signal can range from about 10 MHz to about 200 MHz, e.g., about 100 MHz.

The second dry clean process composition contains fluorine (F) and optionally oxygen (O). For example, the second dry clean process composition may contain NF₃.

The second dry cleaning process step includes: setting a pressure in the plasma processing system; setting one or more flow rates for the second dry clean process composition; and setting a first radio frequency (RF) power level for a first RF signal applied to a substrate holder upon which the substrate rests, wherein the first RF signal has a RF frequency less than or equal to 10 MHz (i.e., the first RF signal may be a low frequency (LF) RF signal). The second dry cleaning process step may further include setting a second radio frequency (RF) power level for a second RF signal applied to the plasma processing system, wherein the second RF signal has a RF frequency greater than 10 MHz (i.e., the second RF signal may be a high frequency (HF) RF signal). Additionally, the second RF signal may be applied to the substrate holder along with the first RF signal.

In one embodiment, the second dry cleaning process step may comprise a process parameter space that includes: a chamber pressure ranging up to about 1000 mTorr (millitorr) (e.g., up to about 200 mTorr, or up to about 100 mTorr, or about 10 to 60 mTorr), a process gas flow rate ranging up to about 2000 sccm (standard cubic centimeters per minute) (e.g., up to about 1000 sccm), a second RF power level coupled to the lower electrode (LEL) (e.g., electrode 522 in FIG. 12) ranging up to about 2000 W (watts), and a first RF power level coupled to the LEL (e.g., electrode 522 in FIG. 12) ranging up to about 1000 W. Also, the RF frequency for the first RF signal can range from about 0.1 MHz to about 10 MHz, e.g., about 3 MHz. In addition, the RF frequency for the second RF signal can range from about 10 MHz to about 200 MHz, e.g., about 100 MHz.

For example, the first RF power level may be set to a value of 100 W or less. Additionally, for example, the first RF power level may be set to a value of 0 W.

Using the multi-step dry cleaning etch process, the first dry cleaning process step may target removal of carbon-containing etch process residue, such as CFₓ, and the second dry cleaning process step may target removal of bromine-containing etch process residue, such as SiBrₓO_{y}, from interior surfaces of the plasma processing system.

The first dry cleaning process step and/or the second dry cleaning process step may be repeated any number of times to complete the multi-step dry cleaning process. For example, the first dry cleaning process step and the second dry cleaning process step may be alternatingly and sequentially performed. Additionally, for example, during each repetition of the first dry cleaning process step and/or the second dry cleaning process step, any one or more of the process parameters identified above may be varied.

Referring again to Table 1, exemplary process conditions for performing a first multi-step dry cleaning (DC) process and a second multi-step dry cleaning (DC) process are provided. Each multi-step DC process condition includes: (a) a first dry cleaning process step using a process composition containing O₂; (b) a second dry cleaning process step using a process composition containing NF₃ and O₂; (c) a third dry cleaning process step using a process composition containing O₂; and (d) a fourth dry cleaning process step using a process composition containing O₂. During the second and fourth dry cleaning process steps, the first RF power level (i.e., LF RF power level) is set to 0 W. The difference between the first and second multi-step DC processes is the etch time for each dry cleaning process step.

As shown in Table 2 (continuing in the etch rate check sequence), the plasma processing system was dry cleaned using the first multi-step DC process condition. The dry cleaning of the plasma processing system using the first multi-step DC process condition included performing the multi-step dry cleaning process condition 1 in Table 1 for a total time duration of 360 sec. Thereafter, an etch rate check was performed that included performing the etch rate check process condition of Table 1 on a blanket oxide (SiO₂) substrate for 300 sec. As presented in Table 2, the etch process condition was substantially returned to the reference etch process condition at an etch rate of 40.5 nm/min (nanometers per minute).

Again, as shown in Table 2, the plasma processing system was dry cleaned using the second multi-step DC process condition. The dry cleaning of the plasma processing system using the second multi-step DC process condition included performing the multi-step dry cleaning process condition 1 in Table 1 for a total time duration of 360 sec, and performing the multi-step dry cleaning process condition 2 in Table 1 for a total time duration of 7200 sec. Thereafter, an etch rate check was performed that included performing the etch rate check process condition of Table 1 on a blanket oxide (SiO₂) substrate for 300 sec. As presented in Table 2, the etch process condition remained substantially at the reference etch process condition at an etch rate of 40.7 nm/min (nanometers per minute).

One or more of the methods for patterning a substrate described above may be performed utilizing a plasma processing system such as the one described in FIG. 12. However, the methods discussed are not to be limited in scope by this exemplary presentation. The method of patterning a substrate according to various embodiments described above may be performed in any one of the plasma processing systems illustrated in FIGS. 5 through 12 and described below.

According to one embodiment, a plasma processing system 500 configured to perform the above identified process conditions is depicted in FIG. 5 comprising a plasma processing chamber 510, substrate holder 520, upon which a substrate 525 to be processed is affixed, and vacuum pumping system 550. Substrate 525 can be a semiconductor substrate, a wafer, a flat panel display, or a liquid crystal display. Plasma processing chamber 510 can be configured to facilitate the generation of plasma in plasma processing region 545 in the vicinity of a surface of substrate 525. An ionizable gas or mixture of process gases is introduced via a gas distribution system 540. For a given flow of process gas, the process pressure is adjusted using the vacuum pumping system 550. Plasma can be utilized to create materials specific to a pre-determined materials process, and/or to aid the removal of material from the exposed surfaces of substrate 525. The plasma processing system 500 can be configured to process substrates of any desired size, such as 200 mm substrates, 300 mm substrates, or larger.

Substrate 525 can be affixed to the substrate holder 520 via a clamping system 528, such as a mechanical clamping system or an electrical clamping system (e.g., an electrostatic clamping system). Furthermore, substrate holder 520 can include a heating system (not shown) or a cooling system (not shown) that is configured to adjust and/or control the temperature of substrate holder 520 and substrate 525. The heating system or cooling system may comprise a re-circulating flow of heat transfer fluid that receives heat from substrate holder 520 and transfers heat to a heat exchanger system (not shown) when cooling, or transfers heat from the heat exchanger system to substrate holder 520 when heating. In other embodiments, heating/cooling elements, such as resistive heating elements, or thermo-electric heaters/coolers can be included in the substrate holder 520, as well as the chamber wall of the plasma processing chamber 510 and any other component within the plasma processing system 500.

Additionally, a heat transfer gas can be delivered to the backside of substrate 525 via a backside gas supply system 526 in order to improve the gas-gap thermal conductance between substrate 525 and substrate holder 520. Such a system can be utilized when temperature control of the substrate is required at elevated or reduced temperatures. For example, the backside gas supply system can comprise a two-zone gas distribution system, wherein the helium gas-gap pressure can be independently varied between the center and the edge of substrate 525.

In the embodiment shown in FIG. 5, substrate holder 520 can comprise an electrode 522 through which RF power is coupled to the processing plasma in plasma processing region 545. For example, substrate holder 520 can be electrically biased at a RF voltage via the transmission of RF power from a RF generator 530 through an optional impedance match network 532 to substrate holder 520. The RF electrical bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Furthermore, the electrical bias of electrode 522 at a RF voltage may be pulsed using pulsed bias signal controller 531. The RF power output from the RF generator 530 may be pulsed between an off-state and an on-state, for example.

Alternately, RF power is applied to the substrate holder electrode at multiple frequencies. Furthermore, impedance match network 532 can improve the transfer of RF power to plasma in plasma processing chamber 510 by reducing the reflected power. Match network topologies (e.g. L-type, π-type, T-type, etc.) and automatic control methods are well known to those skilled in the art.

Gas distribution system 540 may comprise a showerhead design for introducing a mixture of process gases. Alternatively, gas distribution system 540 may comprise a multi-zone showerhead design for introducing a mixture of process gases and adjusting the distribution of the mixture of process gases above substrate 525. For example, the multi-zone showerhead design may be configured to adjust the process gas flow or composition to a substantially peripheral region above substrate 525 relative to the amount of process gas flow or composition to a substantially central region above substrate 525.

Vacuum pumping system 550 can include a turbo-molecular vacuum pump (TMP) capable of a pumping speed up to about 5000 liters per second (and greater) and a gate valve for throttling the chamber pressure. In conventional plasma processing devices utilized for dry plasma etching, a 1000 to 3000 liter per second TMP can be employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the plasma processing chamber 510.

Controller 555 comprises a microprocessor, memory, and a digital I/O port capable of generating control voltages sufficient to communicate and activate inputs to plasma processing system 500 as well as monitor outputs from plasma processing system 500. Moreover, controller 555 can be coupled to and can exchange information with RF generator 530, pulsed bias signal controller 531, impedance match network 532, the gas distribution system 540, vacuum pumping system 550, as well as the substrate heating/cooling system (not shown), the backside gas supply system 526, and/or the electrostatic clamping system 528. For example, a program stored in the memory can be utilized to activate the inputs to the aforementioned components of plasma processing system 500 according to a process recipe in order to perform a plasma assisted process, such as a plasma etch process, on substrate 525.

Controller 555 can be locally located relative to the plasma processing system 500, or it can be remotely located relative to the plasma processing system 500. For example, controller 555 can exchange data with plasma processing system 500 using a direct connection, an intranet, and/or the internet. Controller 555 can be coupled to an intranet at, for example, a customer site (i.e., a device maker, etc.), or it can be coupled to an intranet at, for example, a vendor site (i.e., an equipment manufacturer). Alternatively or additionally, controller 555 can be coupled to the internet. Furthermore, another computer (i.e., controller, server, etc.) can access controller 555 to exchange data via a direct connection, an intranet, and/or the internet.

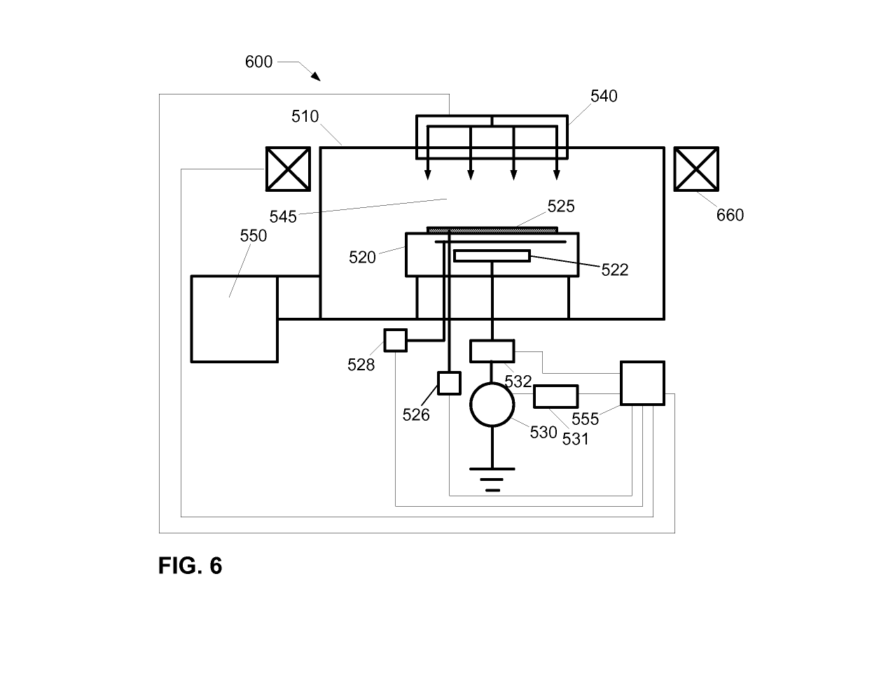

In the embodiment shown in FIG. 6, plasma processing system 600 can be similar to the embodiment of FIG. 5 and further comprise either a stationary, or mechanically or electrically rotating magnetic field system 660, in order to potentially increase plasma density and/or improve plasma processing uniformity, in addition to those components described with reference to FIG. 5. Moreover, controller 555 can be coupled to magnetic field system 660 in order to regulate the speed of rotation and field strength. The design and implementation of a rotating magnetic field is well known to those skilled in the art.

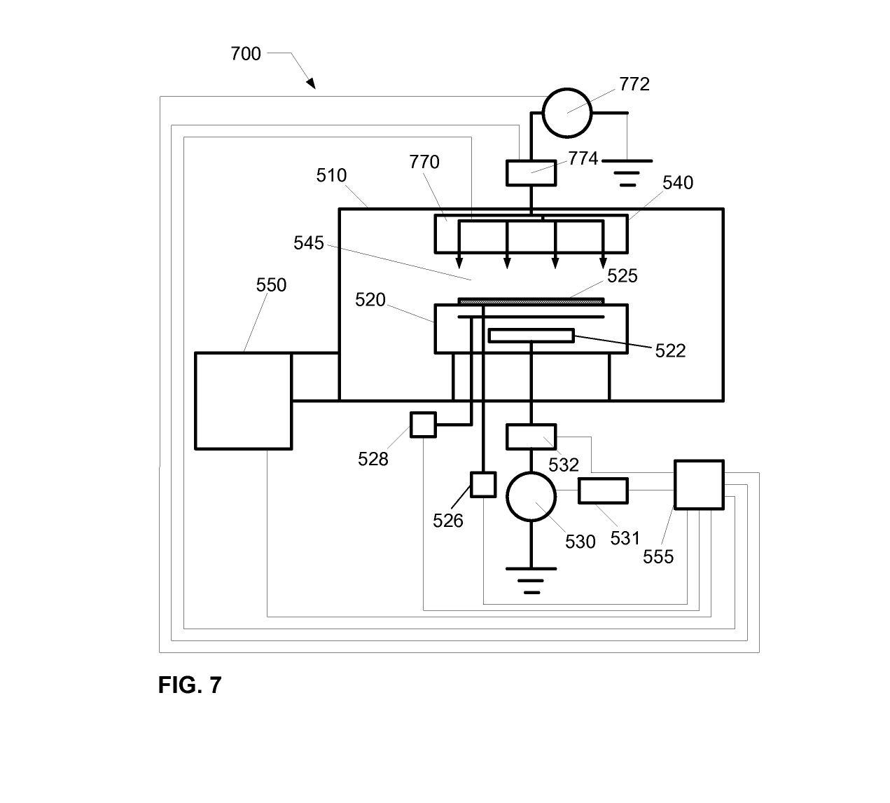

In the embodiment shown in FIG. 7, plasma processing system 700 can be similar to the embodiment of FIG. 5 or FIG. 6, and can further comprise an upper electrode 770 to which RF power can be coupled from RF generator 772 through optional impedance match network 774. A frequency for the application of RF power to the upper electrode can range from about 0.1 MHz to about 200 MHz. Additionally, a frequency for the application of power to the lower electrode can range from about 0.1 MHz to about 100 MHz. Moreover, controller 555 is coupled to RF generator 772 and impedance match network 774 in order to control the application of RF power to upper electrode 770. The design and implementation of an upper electrode is well known to those skilled in the art. The upper electrode 770 and the gas distribution system 540 can be designed within the same chamber assembly, as shown. Alternatively, upper electrode 770 may comprise a multi-zone electrode design for adjusting the RF power distribution coupled to plasma above substrate 525. For example, the upper electrode 770 may be segmented into a center electrode and an edge electrode.

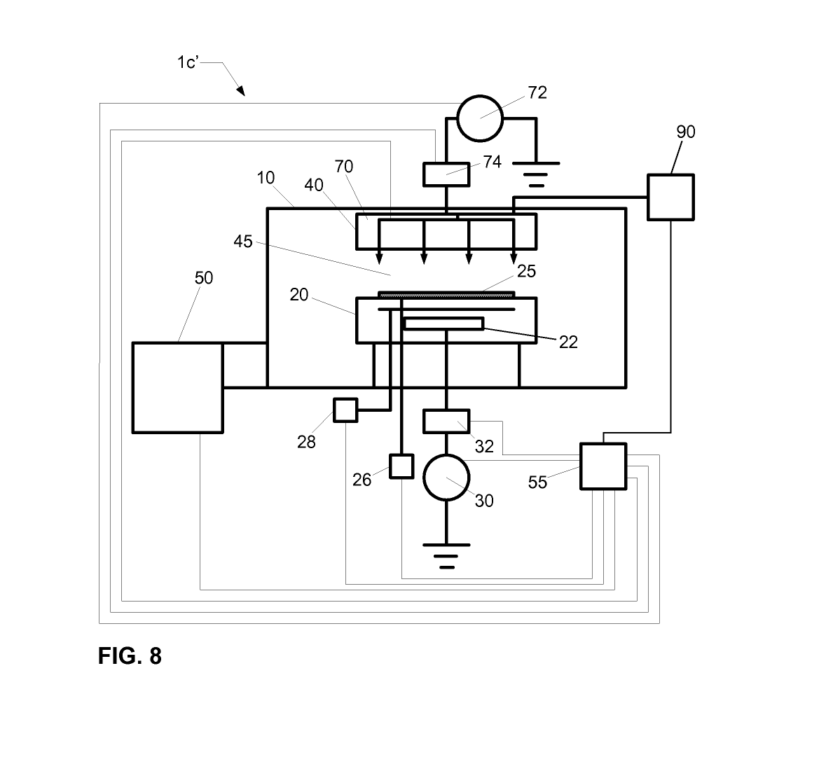

In the embodiment shown in FIG. 8, plasma processing system 800 can be similar to the embodiment of FIG. 7, and can further comprise a direct current (DC) power supply 890 coupled to the upper electrode 770 opposing substrate 525. The upper electrode 770 may comprise an electrode plate. The electrode plate may comprise a silicon-containing electrode plate. Moreover, the electrode plate may comprise a doped silicon electrode plate. The DC power supply 890 can include a variable DC power supply. Additionally, the DC power supply 890 can include a bipolar DC power supply. The DC power supply 890 can further include a system configured to perform at least one of monitoring, adjusting, or controlling the polarity, current, voltage, or on/off state of the DC power supply 890. Once plasma is formed, the DC power supply 890 facilitates the formation of a ballistic electron beam. An electrical filter (not shown) may be utilized to de-couple RF power from the DC power supply 890.

For example, the DC voltage applied to upper electrode 770 by DC power supply 890 may range from approximately −2000 volts (V) to approximately 1000 V. Desirably, the absolute value of the DC voltage has a value equal to or greater than approximately 100 V, and more desirably, the absolute value of the DC voltage has a value equal to or greater than approximately 500 V. Additionally, it is desirable that the DC voltage has a negative polarity. Furthermore, it is desirable that the DC voltage is a negative voltage having an absolute value greater than the self-bias voltage generated on a surface of the upper electrode 770. The surface of the upper electrode 770 facing the substrate holder 520 may be comprised of a silicon-containing material.

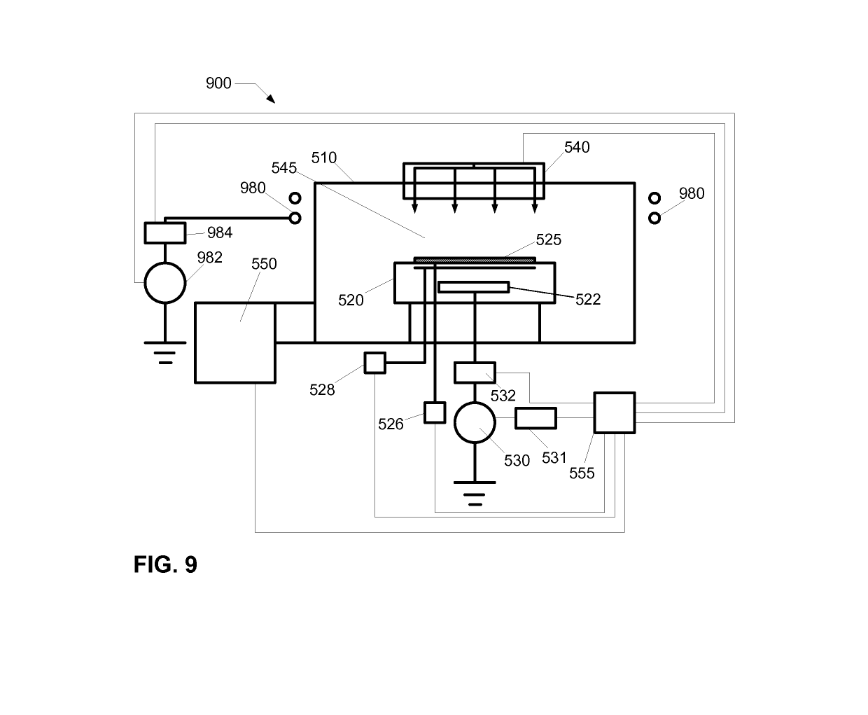

In the embodiment shown in FIG. 9, plasma processing system 900 can be similar to the embodiments of FIGS. 5 and 6, and can further comprise an inductive coil 980 to which RF power is coupled via RF generator 982 through optional impedance match network 984. RF power is inductively coupled from inductive coil 980 through a dielectric window (not shown) to plasma processing region 545. A frequency for the application of RF power to the inductive coil 980 can range from about 10 MHz to about 100 MHz. Similarly, a frequency for the application of power to the chuck electrode can range from about 0.1 MHz to about 100 MHz. In addition, a slotted Faraday shield (not shown) can be employed to reduce capacitive coupling between the inductive coil 980 and plasma in the plasma processing region 545. Moreover, controller 555 can be coupled to RF generator 982 and impedance match network 984 in order to control the application of power to inductive coil 980.

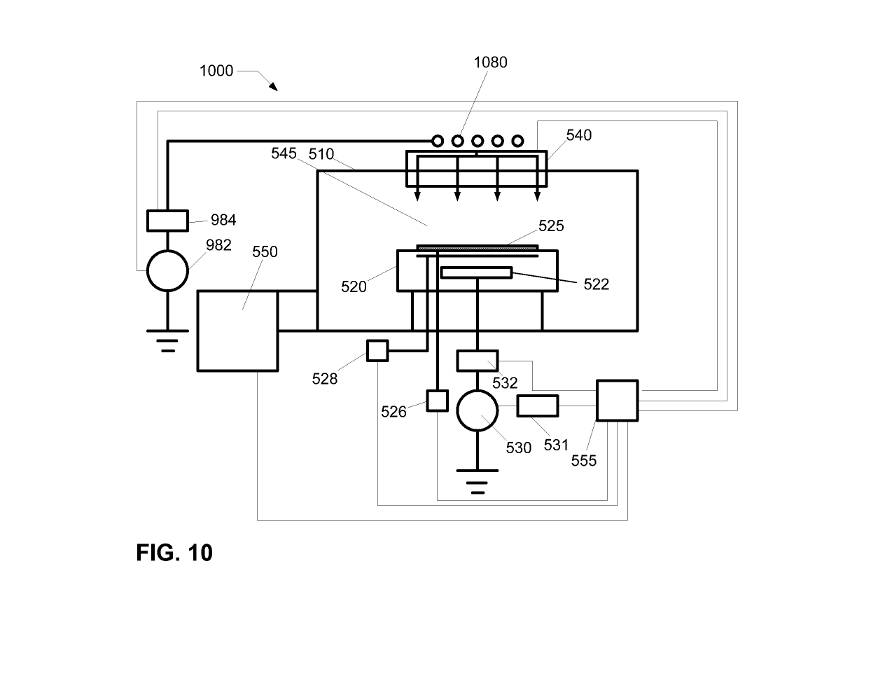

In an alternate embodiment, as shown in FIG. 10, plasma processing system 1000 can be similar to the embodiment of FIG. 9, and can further comprise an inductive coil 1080 that is a “spiral” coil or “pancake” coil in communication with the plasma processing region 545 from above as in a transformer coupled plasma (TCP) reactor. The design and implementation of an inductively coupled plasma (ICP) source, or transformer coupled plasma (TCP) source, is well known to those skilled in the art.

Alternately, plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

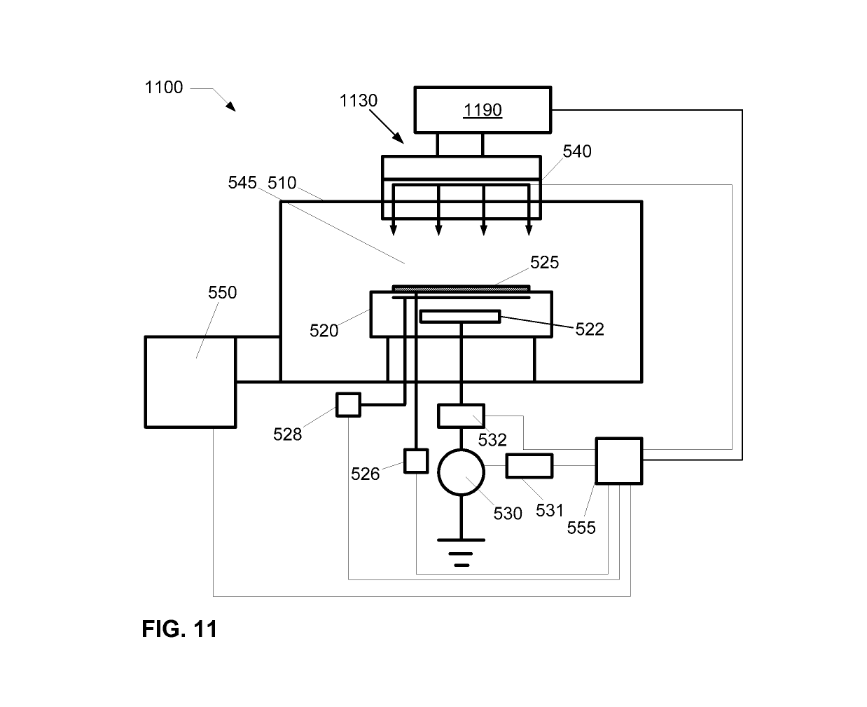

In the embodiment shown in FIG. 11, plasma processing system 1100 can be similar to the embodiment of FIG. 5, and can further comprise a surface wave plasma (SWP) source 1130. The SWP source 1130 can comprise a slot antenna, such as a radial line slot antenna (RLSA), to which microwave power is coupled via a power coupling system 1190.

In the embodiment shown in FIG. 12, plasma processing system 1200 can be similar to the embodiment of FIG. 5, and can further comprise a high frequency (HF) RF generator 1230 for coupling HF RF power through optional impedance match network 1232 to electrode 522 in substrate holder 520. A frequency for the application of HF RF power to the electrode 522 can range from about 10 MHz to about 200 MHz, e.g., 100 MHz. Additionally, a frequency for the application of power to electrode 522 from RF generator 530, which may include a low frequency (LF) RF generator, can range from about 0.1 MHz to about 10 MHz, e.g., 3 MHz. Moreover, controller 555 is coupled to HF RF generator 1230 and impedance match network 1232 in order to control the application of HF RF power to electrode 522.

One or more of the dry cleaning processes described above may be performed utilizing a plasma processing system such as the one described in FIG. 12. However, the methods discussed are not to be limited in scope by this exemplary presentation.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for patterning a substrate, comprising:
establishing a reference etch process condition for a plasma processing system;
transferring a mask pattern formed in a mask layer to one or more layers on a substrate using at least one plasma etching process in said plasma processing system to form a feature pattern in said one or more layers; and
following said transferring, performing a multi-step dry cleaning process to substantially recover said reference etch process condition, said multi-step dry cleaning process comprising:
performing a first dry cleaning process step using plasma formed from a first dry clean process composition containing an oxygen-containing gas, and
performing a second dry cleaning process step using plasma formed from a second dry clean process composition containing a halogen-containing gas.

2. The method of claim 1, further comprising:
repeating said first dry cleaning process step and/or said second dry cleaning process step.

3. The method of claim 1, further comprising:
preparing a multi-layer film stack including said one or more layers on said substrate, said multi-layer film stack having alternating layers of differing composition including one or more layers of a first composition and one or more layers of a second composition; and
preparing said mask layer on said multi-layer film stack and forming said mask pattern in said mask layer.

4. The method of claim 3, wherein said first composition includes Si and one or more elements selected from the group consisting of O, N, C, and H, and said second composition includes Si.

5. The method of claim 3, wherein said first composition is SiO₂ and said second composition is Si.

6. The method of claim 1, wherein said reference etch process condition comprises an etch rate of at least one of said layers of differing material composition, an etch selectivity between two or more of said layers of differing material composition, a critical dimension (CD) for said feature pattern formed in at least one of said layers of differing material composition, or a CD bias for said feature pattern, or any combination of two or more thereof.

7. The method of claim 6, wherein said reference etch process condition comprises an etch uniformity of said etch rate, said etch selectivity, said critical dimension, or said CD bias, or a combination of two or more thereof.

8. The method of claim 6, wherein said reference etch process condition includes an etch rate of a reference material on a reference substrate.

9. The method of claim 1, wherein said first dry clean process composition contains oxygen.

10. The method of claim 1, wherein said first dry clean process composition contains O, O₂, O₃, CO, CO₂, NO, N₂O, or NO₂, or any combination of two or more thereof.

11. The method of claim 1, wherein said second dry clean process composition contains fluorine and optionally oxygen.

12. The method of claim 1, wherein said second dry clean process composition contains NF₃.

13. The method of claim 1, wherein said first dry cleaning process step includes:
setting a pressure in said plasma processing system;
setting one or more flow rates for said first dry clean process composition; and
setting a first radio frequency (RF) power level for a first RF signal applied to a substrate holder upon which said substrate rests, said first RF signal having a RF frequency less than or equal to 10 MHz.

14. The method of claim 13, wherein said first dry cleaning process step further includes:
setting a second radio frequency (RF) power level for a second RF signal applied to said plasma processing system, said second RF signal having a RF frequency greater than 10 MHz.

15. The method of claim 1, wherein said second dry cleaning process step includes:
setting a pressure in said plasma processing system;
setting one or more flow rates for said second dry clean process composition; and
setting a first radio frequency (RF) power level for a first RF signal applied to a substrate holder upon which said substrate rests, said first RF signal having a RF frequency less than or equal to 10 MHz.

16. The method of claim 15, wherein said second dry cleaning process step further includes:
setting a second radio frequency (RF) power level for a second RF signal applied to said plasma processing system, said second RF signal having a RF frequency greater than 10 MHz.

17. The method of claim 15, wherein said first RF power level is set to a value of 100 W or less.

18. The method of claim 15, wherein said first RF power level is set to a value of 0 W.

19. The method of claim 1, wherein said first dry cleaning process step removes a first etch process residue on interior surfaces of said plasma processing system, and said second dry cleaning process step removes a second etch process residue on interior surfaces of said plasma processing system.

20. The method of claim 19, wherein said first etch process residue contains C, and said second etch process residue contains Br.
